(19) United States
(12) Patent Application Publication
(10) Pub. No.: US 2026/0247697 A1
(43) Pub. Date: Aug. 20, 2026

(54) SEMICONDUCTOR DEVICE INCLUDING NANOSHEET STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Zhi-Ren XIAO, Hsinchu (TW); Nuo XU, Hsinchu (TW); Chih-Ching WANG, Hsinchu (TW); Zhiqiang WU, Hsinchu (TW)

(73) Assignee: TAIWAN SEMICONDUCTOR MANUFACTURING COMPANY, LTD., Hsinchu (TW)

(21) Appl. No.: 19/057,690

(22) Filed: Feb. 19, 2025

(51) Int. Cl. H10D 84/83; H01L 21/265; H01L 21/324; H10D 30/00; H10D 30/01; H10D 30/43; H10D 62/00; H10D 62/10; H10D 62/13; H10D 62/40; H10D 62/832; H10D 62/834; H10D 84/01

(52) U.S. Cl. CPC H10D 84/832; H10D 30/014; H10D 30/0191; H10D 30/43; H10D 30/502; H10D 62/021; H10D 62/121; H10D 62/151; H10D 62/40; H10D 62/832; H10D 62/834; H10D 84/013; H10D 84/0149; H10P 30/204; H10P 30/212; H10P 95/90

(57) ABSTRACT

A method for manufacturing a semiconductor device includes: forming a fin structure on a substrate, the fin structure including a plurality of sacrificial layer portions and a plurality of channel layer portions which are alternately stacked in a normal direction relative to the substrate; forming a trench that penetrates the fin structure, so that the plurality of sacrificial layer portions are formed into a plurality of sacrificial features, and the plurality of channel layer portions are formed into a plurality of channel features; forming a plurality of upper epitaxial portions, a plurality of lower epitaxial portions and a plurality of intermediate epitaxial portions in the trench; amorphizing the plurality of upper epitaxial portions and the plurality of intermediate epitaxial portions; forming an epitaxial layer to fill the trench; and subjecting the plurality of upper epitaxial portions and the plurality of intermediate epitaxial portions to recrystallization.

### BACKGROUND

With continuous development of semiconductor technology, functionality and electrical performance of transistors (e.g., nanosheet transistors, forksheet transistors, etc.) are being continuously improved. The nanosheet transistors have wide applications due to superior electrical performance. However, manufacturing quality of the nanosheet transistors may be adversely affected by some process issues, which may have impact on the functionality and the electrical performance of the nanosheet transistors. The semiconductor industry is devoted to solving these process issues.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2A to 15C are schematic views illustrating some intermediate stages of the method as depicted in FIGS. 1A and 1B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “intermediate,” “lower,” “uppermost,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

A semiconductor device including a plurality of nanosheet transistors (e.g., nanosheet field-effect transistors (FETs)) has wide applications due to superior device performance. A nanosheet FET structure is a type of a gate-all-around FET (GAAFET) structure. A semiconductor device including nanosheet transistors includes a semiconductor substrate (e.g., a (110) silicon wafer having a horizontal direction of <110>or <100>and a vertical direction of <110>), a plurality of source/drain regions disposed on the semiconductor substrate, and other elements. In the nanosheet transistors, the plurality of source/drain regions (made of a semiconductor material, e.g., silicon, silicon boron, silicon germanium, silicon phosphide, silicon arsenic, etc.) are formed by a selective epitaxial growth (SEG) process. Each of the source/drain regions may have a high crystallinity and a predetermined geometry (shape). However, due to a vertical loading effect, a growth rate of the semiconductor material formed in an upper portion of each of the source/drain regions is greater than a growth rate of the semiconductor material in an intermediate portion or a lower portion of each of the source/drain regions, which may result in lateral merge of the semiconductor material during an early stage of forming the source/drain regions, and thus induce formation of defects (e.g., voids) in the source/drain regions.

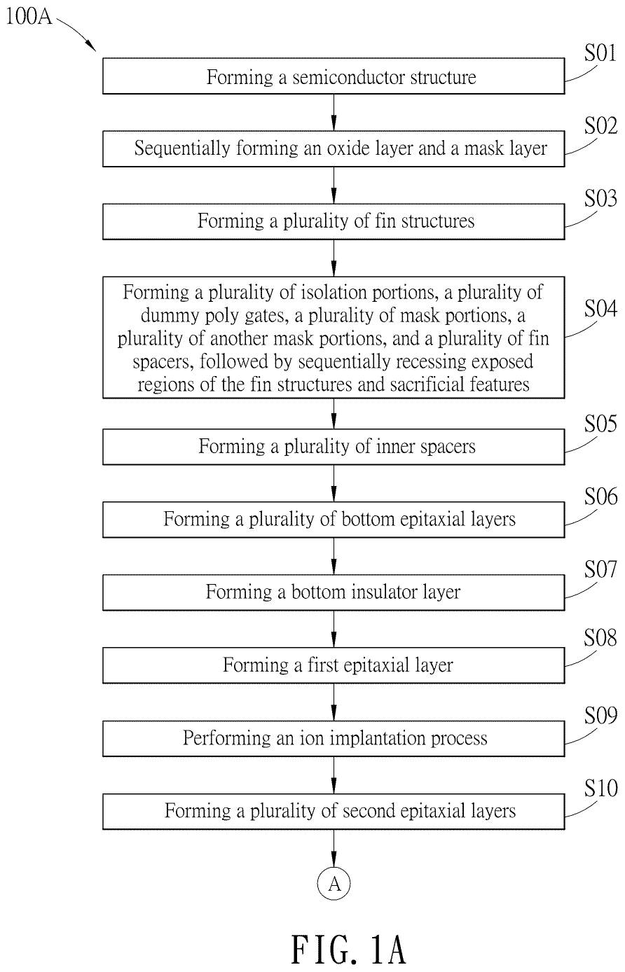

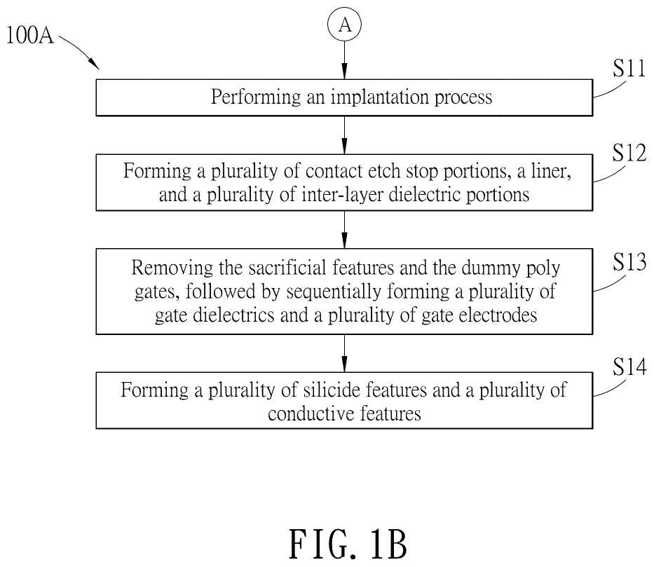

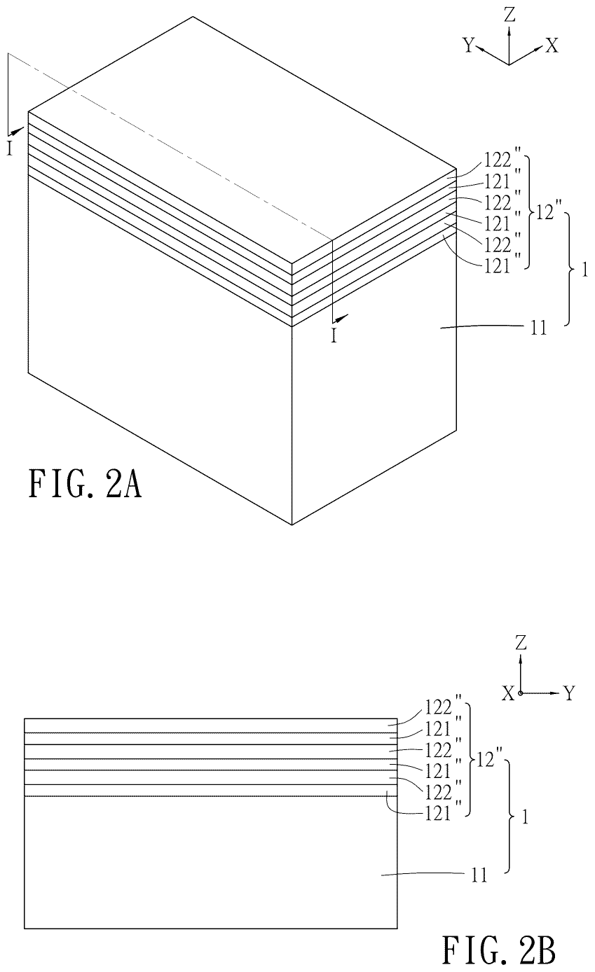

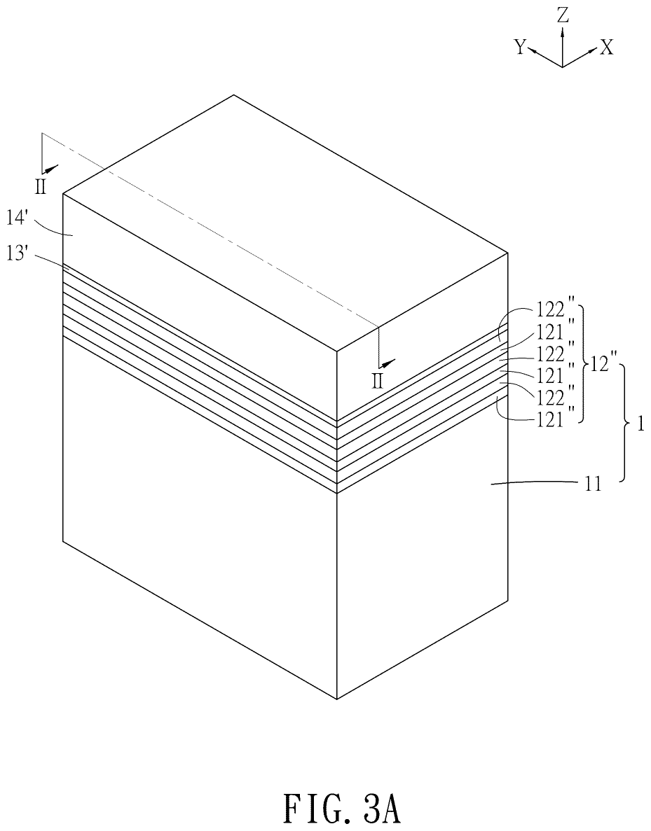

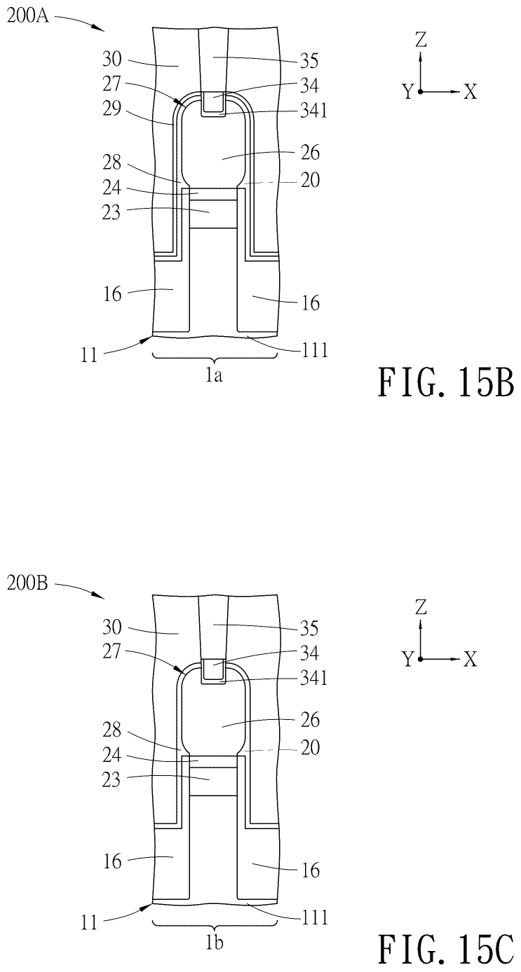

The present disclosure is directed to a semiconductor device and a method for manufacturing the same. FIGS. 1A and 1B are flow diagrams illustrating a method 100A for manufacturing a first semiconductor device 200A shown in FIGS. 15A and 15B and a second semiconductor device 200B shown in FIGS. 15A and 15C in accordance with some embodiments. FIGS. 2A to 14C illustrate schematic views of some intermediate stages of the method 100A. Some portions may be omitted in FIGS. 2A to 14C for the sake of brevity. Additional steps can be provided before, after or during the method 100A, and some of the steps described herein may be replaced by other steps or be eliminated.

Referring to FIG. 1A and the example illustrated in FIGS. 2A and 2B, the method 100A begins at step S01, where a semiconductor structure 1 is formed. FIG. 2B illustrates a cross-sectional view taken along line I-I of FIG. 2A. The semiconductor structure 1 includes a semiconductor substrate 11 and a nanosheet stack 12″.

The semiconductor substrate 11 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure.

The nanosheet stack 12″ is disposed on the semiconductor substrate 11 in a Z direction normal to the semiconductor substrate 11. The nanosheet stack 12″ includes a plurality of sacrificial layers 121″ and a plurality of channel layers 122″ disposed to alternate with the sacrificial layers 121″ in the Z direction. In some embodiments, the nanosheet stack 12″ is a stack of semiconductor materials. In some embodiments, the sacrificial layers 121″ are made of a first semiconductor material, and the channel layers 122″ are made of a second semiconductor material that is different from the first semiconductor material, so that each layer of the channel layers 122″ has an etching selectivity (or an etching rate) different from that of each layer of the sacrificial layers 121″. In some embodiments, the first semiconductor material may be silicon germanium, and the second semiconductor material may be silicon, so that each layer of the sacrificial layers 121″ has an etching selectivity (or an etching rate) greater than that of each layer of the channel layers 122″. In some embodiments, the nanosheet stack 12″ may be formed on the semiconductor substrate 11 by a suitable deposition process (for example, but not limited to, chemical vapor deposition (CVD), atomic layer deposition (ALD), etc.), or a suitable epitaxial growth process (for example, but not limited to, molecular beam epitaxy (MBE), the SEG process, etc.). Other suitable processes for forming the nanosheet stack 12″ are within the contemplated scope of the present disclosure.

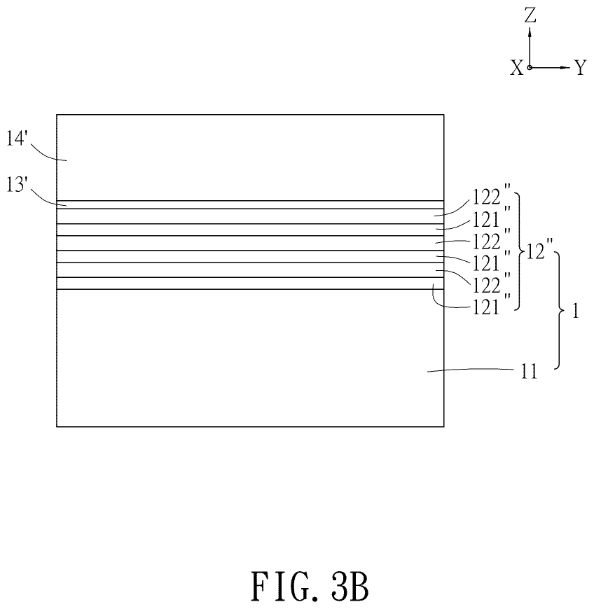

Referring to FIG. 1A and the example illustrated in FIGS. 3A and 3B, the method 100A then proceeds to step S02, where an oxide layer 13′ and a mask layer 14′ are sequentially formed on the semiconductor structure 1. FIG. 3B illustrates a cross-sectional view taken along line II-II of FIG. 3A. In some embodiments, the oxide layer 13′ may include, for example, but not limited to, silicon oxide. Other suitable materials for forming the oxide layer 13′ are within the contemplated scope of the present disclosure. In some embodiments, the oxide layer 13′ may be formed by a suitable deposition process, for example, but not limited to, CVD or ALD. Other suitable deposition processes for forming the oxide layer 13′ are within the contemplated scope of the present disclosure. In some embodiments, the mask layer 14′ may be made of a nitride-based material, which may include, for example, but not limited to, silicon nitride. Other suitable materials for forming the mask layer 14′ are within the contemplated scope of the present disclosure. In some embodiments, the mask layer 14′ may be formed by a suitable deposition process, for example, but not limited to, CVD or ALD. Other suitable deposition processes for forming the mask layer 14′ are within the contemplated scope of the present disclosure.

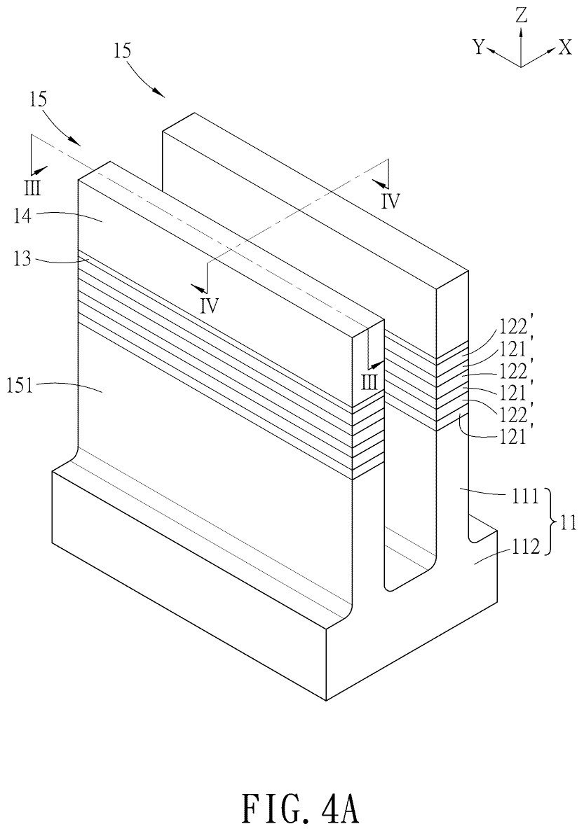

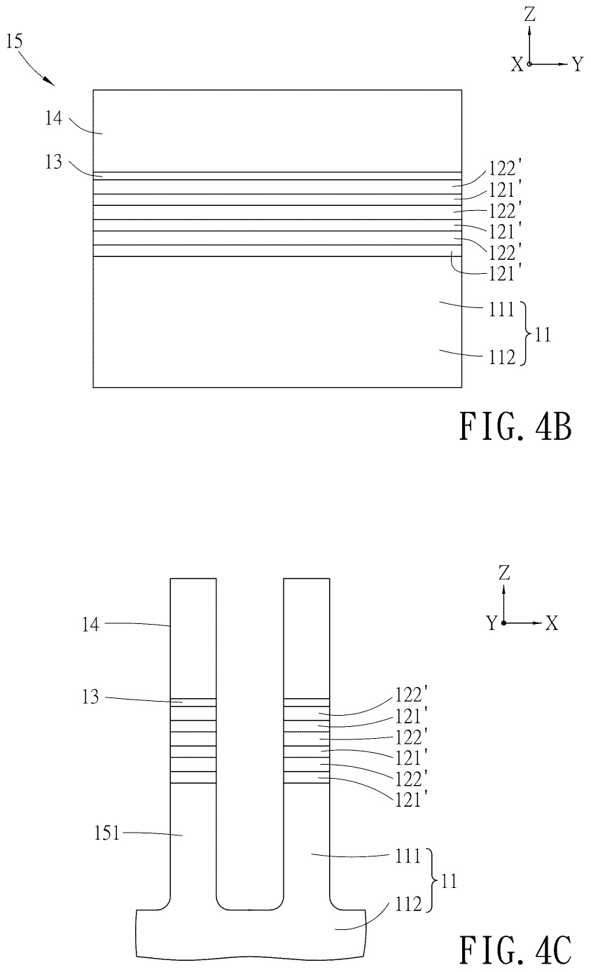

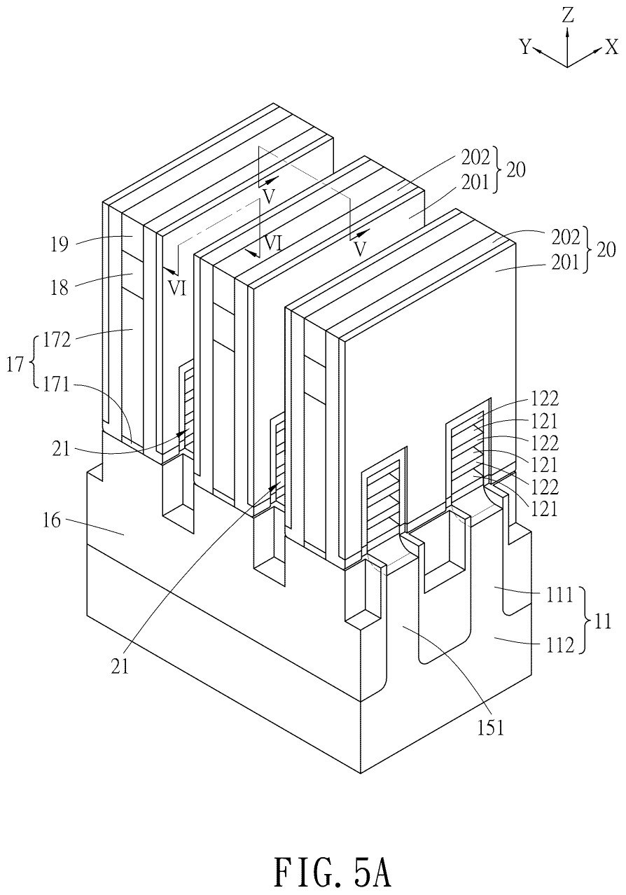

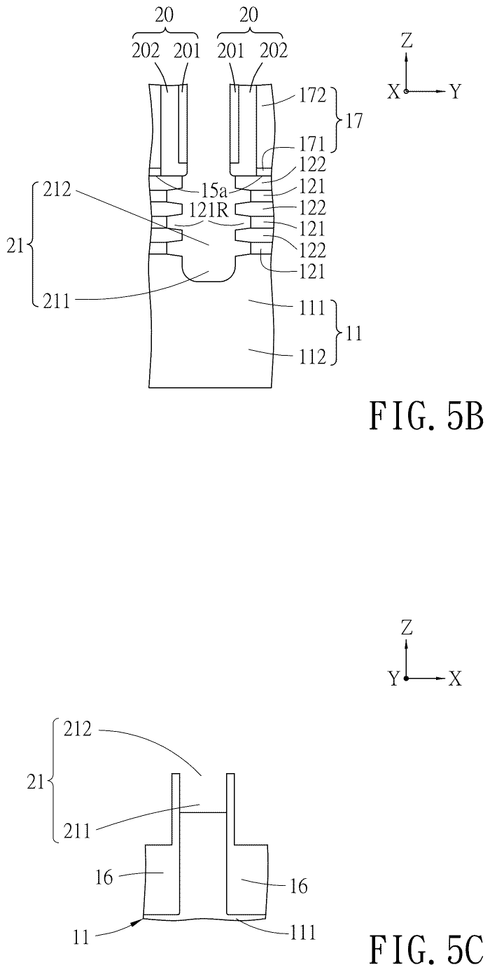

Referring to FIG. 1A and the example illustrated in FIGS. 4A to 4C, the method 100A then proceeds to step S03, where the semiconductor structure 1 is patterned to form a plurality of fin structures 15. FIG. 4B illustrates a cross-sectional view taken along line III-III of FIG. 4A. FIG. 4C illustrates a cross-sectional view taken along line IV-IV of FIG. 4A. Step S03 may be performed by a photolithography process, which includes an etching process. The etching process may be, for example, but not limited to, an anisotropic etching process. A plurality of trenches are formed to penetrate the mask layer 14′, the oxide layer 13′, the nanosheet stack 12″ and an upper portion 111 of the semiconductor substrate 11, and terminate at a lower portion 112 of the semiconductor substrate 11. After this step, the sacrificial layers 121″ are formed into a plurality of sacrificial layer portions 121′, the channel layers 122″ are formed into a plurality of channel layer portions 122′, the oxide layer 13′ is formed into a plurality of oxide layer portions 13, and the mask layer 14′ is formed into a plurality of mask layer portions 14. The fin structures 15 are spaced apart from each other by the trenches in an X direction and extend in a Y direction. The X direction is transverse to the Z direction and parallel to the semiconductor substrate 11, and the Y direction is transverse to the X direction and the Z direction. In some embodiments, the X, Y, and Z directions are perpendicular to one another. Each of the fin structures 15 includes a fin portion 151 (formed from the upper portion 111 of the semiconductor substrate 11) disposed on the lower portion 112 of the semiconductor substrate 11, corresponding ones of the sacrificial layer portions 121′, corresponding ones of the channel layer portions 122′ disposed to alternate with the corresponding ones of the sacrificial layer portions 121′ in the Z direction, a corresponding one of the oxide layer portions 13, and a corresponding one of the mask layer portions 14. In some embodiments, an upper surface of each of the fin structures 15 may have a plurality of covered regions 15a (see FIG. 5B) and a plurality of exposed regions (not shown) that are alternated with one another in the Y direction.

Referring to FIG. 1A and the example illustrated in FIGS. 5A to 5C, the method 100A then proceeds to step S04, where a plurality of isolation portions 16, a plurality of dummy poly gates 17, a plurality of mask portions 18, a plurality of mask portions 19, and a plurality of fin spacers 20 are formed, followed by sequentially recessing the exposed regions of the fin structures 15 and sacrificial features 121. FIG. 5B illustrates a cross-sectional view taken along line V-V of FIG. 5A. FIG. 5C illustrates a cross-sectional view taken along line VI-VI of FIG. 5A. The dummy poly gates 17, the mask portions 18, and the mask portions 19 are formed on the isolation portions 16 and over the fin structures 15. Each of the dummy poly gates 17 includes a dummy gate dielectric 171 (i.e., a plurality of the dummy gate dielectrics 171 are formed in this step) and a dummy gate electrode 172 (i.e., a plurality of the dummy gate electrodes 172 are formed in this step).

In this step, the isolation portions 16 are firstly formed on the lower portion 112 of the semiconductor substrate 11. Each pair of the isolation portions 16 is located at two opposite sides of the fin portion 151 of a corresponding one of the fin structures 15, so as to separate and isolate the fin structures 15 from each other. The two opposite sides of the fin portion 151 of a corresponding one of the fin structures 15 are opposite to each other in the X direction (see FIG. 4). In some embodiments, the isolation portions 16 may include an oxide-based material (e.g., silicon oxide), a nitride-based material (e.g., silicon nitride), or a combination thereof. Other suitable materials for forming the isolation portions 16 are within the contemplated scope of the present disclosure. In some embodiments, the isolation portions 16 may be formed by a suitable deposition process, for example, but not limited to, CVD or physical vapor deposition (PVD) so as to form an isolation material layer on the structure shown in FIG. 4A, followed by conducting an etching back process to remove a portion of the isolation material layer. Other suitable processes for forming the isolation portions 16 are within the contemplated scope of the present disclosure. In some embodiments, each of the isolation portions 16 may be a portion of a shallow trench isolation (STI), a deep trench isolation (DTI), or other suitable isolation structures.

Secondly, a first dummy layer (not shown) for forming the dummy gate dielectrics 171 is conformally formed on the structure obtained after formation of the isolation portions 16. In some embodiments, the first dummy layer may be made of an oxide-based material (e.g., silicon oxide). Other suitable materials for forming the first dummy layer are within the contemplated scope of the present disclosure. In some embodiments, the first dummy layer may be formed by a suitable deposition process, for example, but not limited to, CVD, ALD, or PVD. Other suitable processes for forming the first dummy layer are within the contemplated scope of the present disclosure.

Next, a second dummy layer (not shown) for forming the dummy gate electrodes 172 is formed on the structure obtained after formation of the first dummy layer, followed by conducting a planarization process to remove an excess portion of the second dummy layer. In some embodiments, the second dummy layer may include, for example, but not limited to, polysilicon. Other suitable materials for forming the second dummy layer are within the contemplated scope of the present disclosure. In some embodiments, the second dummy layer may be formed by a suitable deposition process, for example, but not limited to, CVD, ALD, or PVD. Other suitable processes for forming the second dummy layer are within the contemplated scope of the present disclosure. In some embodiments, the planarization process may be a chemical mechanical polishing (CMP) or other suitable planarization processes.

Thereafter, a mask material layer (not shown) for forming the mask portions 18 and a mask material layer (not shown) for forming the mask portions 19 are formed sequentially on the structure obtained after formation of the second dummy layers. In some embodiments, the mask material layer for forming the mask portions 18 may include an oxide-based material (e.g., silicon oxide), and the mask material layer for forming the mask portions 18 may include a nitride-based material (e.g., silicon nitride). Other suitable materials for forming the mask material layers are within the contemplated scope of the present disclosure.

Then, the structure obtained after formation of the mask material layers is patterned by a photolithography process, which includes an etching process, thereby obtaining the dummy poly gates 17, the mask portions 18, and the mask portions 19.

The dummy gate dielectric 171 of each of the dummy poly gates 17 is disposed on a corresponding one of the covered regions 15a of each of the fin structures 15. The dummy gate electrode 172 is disposed on the dummy gate dielectric 171. Each of the mask portions 18 is disposed on a corresponding one of the dummy poly gates 17. Each of the mask portions 19 is disposed on a corresponding one of the mask portions 18 opposite to a corresponding one of the dummy poly gates 17.

After that, each pair of the fin spacers 20 is respectively formed at two opposite sides of a corresponding one of the dummy poly gates 17 in the Y direction. In some embodiments, each of the fin spacers 20 may be formed as a single layer structure or a multi-layered structure. In some embodiments, when each of the fin spacers 20 is formed as the multi-layered structure (e.g., a two-layered structure), each of the fin spacers 20 may include an outer part 201 and an inner part 202 disposed between a corresponding one of the dummy poly gates 17 and the outer part 201. The fin spacers 20 may be formed by sequentially depositing two spacer material layers on the mask portions 19 and the exposed regions of the fin structures 15 by a suitable deposition process, for example, but not limited to, CVD, ALD, or other suitable deposition processes, followed by performing an anisotropic dry etching process until portions of the spacer material layers, which are respectively formed on the exposed regions of the fin structures 15 and an upper surface of each of the mask portions 19, are removed such that remaining portions of the spacer material layers serve as the fin spacers 20. In some embodiments, the spacer material layers for forming the fin spacers 20 may include, for example, but not limited to, silicon oxide, silicon nitride, silicon oxynitride, silicon carbon nitride, silicon oxycarbonnitride, low-dielectric constant (k) materials, or combinations thereof. Other suitable materials for forming the fin spacers 20 are within the contemplated scope of the present disclosure.

Afterwards, an etching process (e.g., an anisotropic dry etching process or other suitable etching processes) is performed on the structure obtained after formation of the fin spacers 20 to remove portions of the fin structures 15 through the exposed regions thereof. After the etching process, a plurality of source/drain trenches 21 are formed, each of the fin structures 15 is formed into a plurality of stack sections, each of the sacrificial layer portions 121′ is formed into the sacrificial features 121, and each of the channel layer portions 122′ is formed into a plurality of channel features 122. Each of the stack sections includes corresponding ones of the sacrificial features 121 and corresponding ones of the channel features 122 that are alternated with one another in the Z direction. In some embodiments, the source/drain trenches 21 are spaced apart from one another in the Y direction. In some embodiments, each of the source/drain trenches 21 includes a lower trench portion 211 and an upper trench portion 212 formed above and in spatial communication with the lower trench portion 211.

The sacrificial features 121 are then laterally recessed by an isotropic etching process, for example, but not limited to, a wet etching process or other suitable etching processes to remove side portions of the sacrificial features 121 based on a relatively high etching selectivity of the sacrificial features 121 with respect to the channel features 122, so as to form a plurality of lateral recesses 121R (see FIG. 5B).

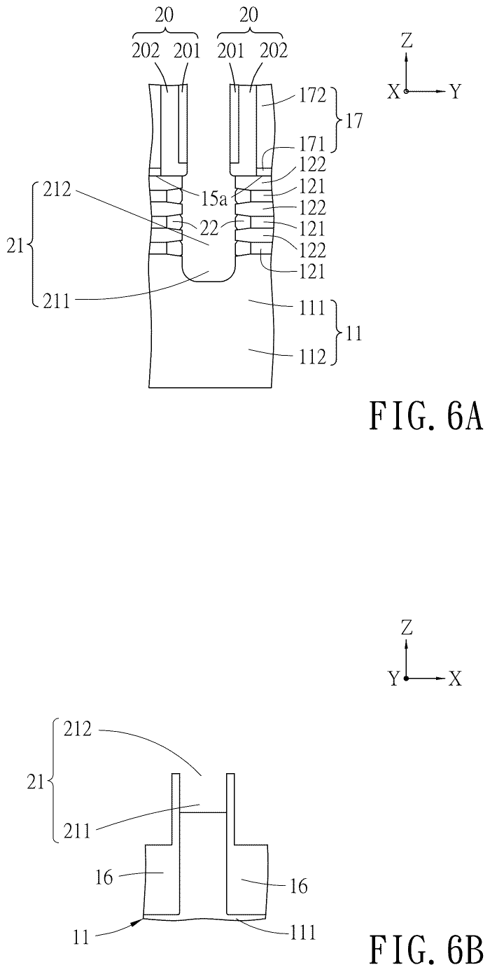

Referring to FIG. 1A and the example illustrated in FIGS. 6A and 6B, the method 100A then proceeds to step S05, where a plurality of inner spacers 22 are formed. Step S05 may be performed by forming an inner spacer material layer (not shown) on the structure shown in FIG. 5A or 5B, such that the inner spacer material layer fills the lateral recesses 121R, followed by performing an etching process to remove an excess portion of the inner spacer material layer, thereby obtaining the inner spacers 22. FIG. 6B illustrates a structure obtained after step S05, and the structure shown in FIG. 6B is the same as that shown in FIG. 5C. In some embodiments, the inner spacer material layer may include, for example, but not limited to, silicon oxide, silicon nitride, silicon carbide, silicon oxycarbide, silicon oxynitride, silicon carbonitride, silicon oxycarbonitride, low-k materials, or combinations thereof. Other suitable materials for forming the inner spacer material layer are within the contemplated scope of the present disclosure. In some embodiments, the inner spacer material layer may be formed by a suitable deposition process, for example, but not limited to, CVD or ALD. Other suitable deposition processes for forming the inner spacer material layer are within the contemplated scope of the present disclosure. In some embodiments, the etching process may be a dry etching process, a wet etching process, or a combination thereof.

In some embodiments, in step S04, the sacrificial features 121 may be fully removed so as to form a plurality of spaces (not shown). Afterwards, an oxide-based material (for example, but not limited to, silicon oxide) may be used to fill the source/drain trenches 21 and the spaces, followed by performing an isotropic etching process to remove an excess portion of the oxide-based material, so as to form a plurality of interposers (not shown). In some embodiments, each of the interposers is laterally recessed during the isotropic etching process (i.e., being over etched) to form a plurality of lateral recesses (not shown), and then the inner spacers 22 are formed in the lateral recesses, respectively. In some embodiments, each of the interposers may not be laterally recessed in the isotropic etching process. In this case, the inner spacers 22 may not be formed (i.e., step S05 may be omitted).

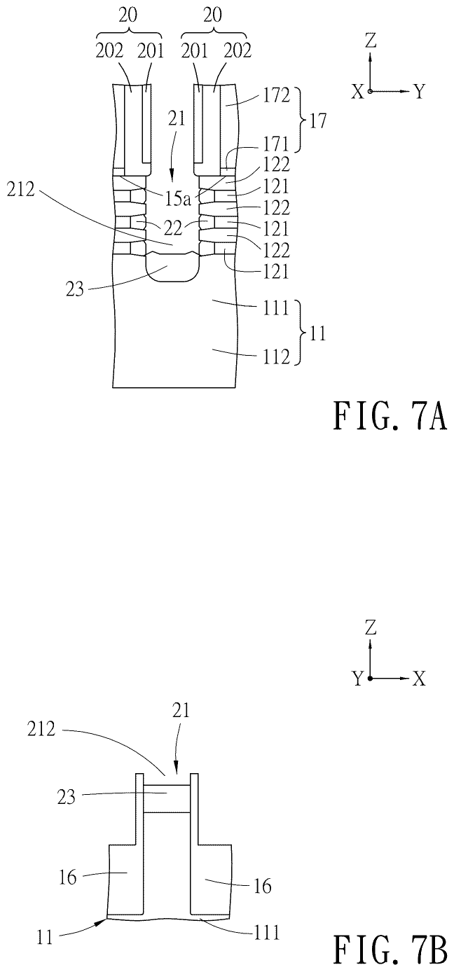

Referring to FIG. 1A and the example illustrated in FIGS. 7A and 7B, the method 100A then proceeds to step S06, where a plurality of bottom epitaxial layers 23 are formed in the lower trench portions 211 of the source/drain trenches 21 (see FIGS. 6A and 6B), respectively. FIG. 7B illustrates a structure obtained after step S06, and the structure shown in FIG. 7B is similar to that shown in FIG. 6B except for inclusion of the bottom epitaxial layers 23. In some embodiments, the bottom epitaxial layers 23 may be made of or include, for example, but not limited to, silicon, which is undoped or unintentionally doped. In some embodiments, the bottom epitaxial layers 23 may be formed by a suitable epitaxial growth process, for example, but not limited to, the SEG process.

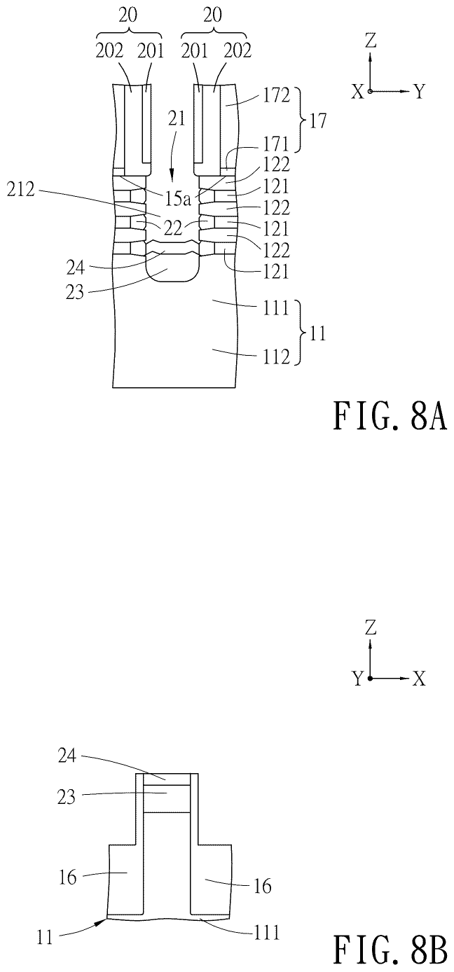

Referring to FIG. 1A and the example illustrated in FIGS. 8A and 8B, the method 100A then proceeds to step S07, where a bottom insulator layer 24 is formed on the structure shown in FIGS. 7A and 7B. FIG. 8B illustrates a structure obtained after step S07, and the structure shown in FIG. 8B is similar to that shown in FIG. 7B except for inclusion of the bottom insulator layer 24. In some embodiments, the bottom insulator layer 24 may be made of a dielectric material, for example, but not limited to, silicon nitride, silicon oxide, silicon oxynitride, or combinations thereof. Other suitable materials for forming the bottom insulator layer 24 are within the contemplated scope of the present disclosure. In some embodiments, the bottom insulator layer 24 may be formed by a suitable deposition process, for example, but not limited to, CVD or ALD. Other suitable deposition processes for forming the bottom insulator layer 24 are within the contemplated scope of the present disclosure.

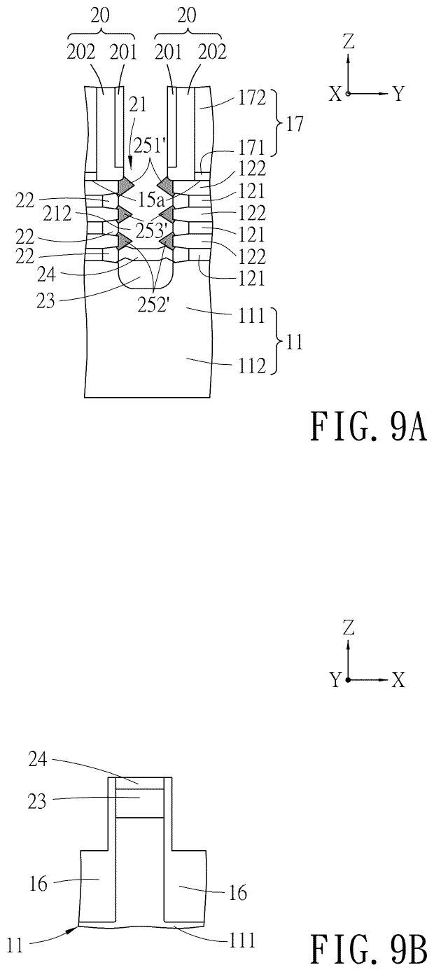

Referring to FIG. 1A and the example illustrated in FIGS. 9A and 9B, the method 100A then proceeds to step S08, where a first epitaxial layer is formed in the upper trench portion 212 of each of the source/drain trenches 21. FIG. 9B illustrates a structure obtained after step S08, and the structure is similar to that shown in FIG. 8B except for inclusion of the first epitaxial layer. The first epitaxial layer includes a plurality of epitaxial portions, each of which is disposed at a side of a corresponding one of the channel features 122. In some embodiments, the first epitaxial layer includes or is made of, for example, but not limited to, silicon, silicon germanium, silicon boron, silicon phosphide, silicon arsenic, or combinations thereof. In some embodiments in which p-type metal oxide semiconductor field-effect transistors (PMOSFETs) are to be formed, the first epitaxial layer includes or is made of, for example, but not limited to, silicon, silicon germanium, silicon boron, or combinations thereof. In some embodiments in which n-type metal oxide semiconductor field-effect transistors (NMOSFETs) are to be formed, the first epitaxial layer includes or is made of, for example, but not limited to, silicon, silicon germanium, silicon phosphide, silicon arsenic, or combinations thereof. In some embodiments, the first epitaxial layer may be formed by a suitable epitaxial growth process, for example, but not limited to, the SEG process. In some embodiments, the first epitaxial layer includes upper epitaxial portions 251′ that are distal from the semiconductor substrate 11 in the Z direction, lower epitaxial portions 252′ that are proximate to the semiconductor substrate 11 in the Z direction, and intermediate epitaxial portions 253′ that are located between the upper epitaxial portions 251′ and the lower epitaxial portions 252′ in the Z direction. In some embodiments, a structure of each of the upper epitaxial portions 251′, the lower epitaxial portions 252′, and the intermediate epitaxial portions 253′ may have a diamond shape. Other geometrical shapes for the structure of each of the upper epitaxial portions 251′, the lower epitaxial portions 252′, and the intermediate epitaxial portions 253′ are within the contemplated scope of the present disclosure. In some embodiments, each of the upper epitaxial portions 251′, the lower epitaxial portions 252′, and the intermediate epitaxial portions 253′ may have a thickness ranging from about 3 nm to about 5 nm which is measured in the Y direction.

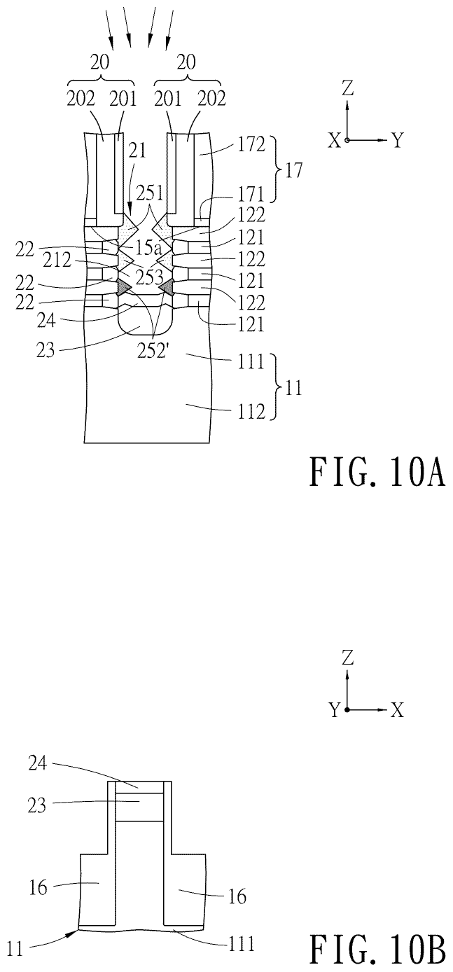

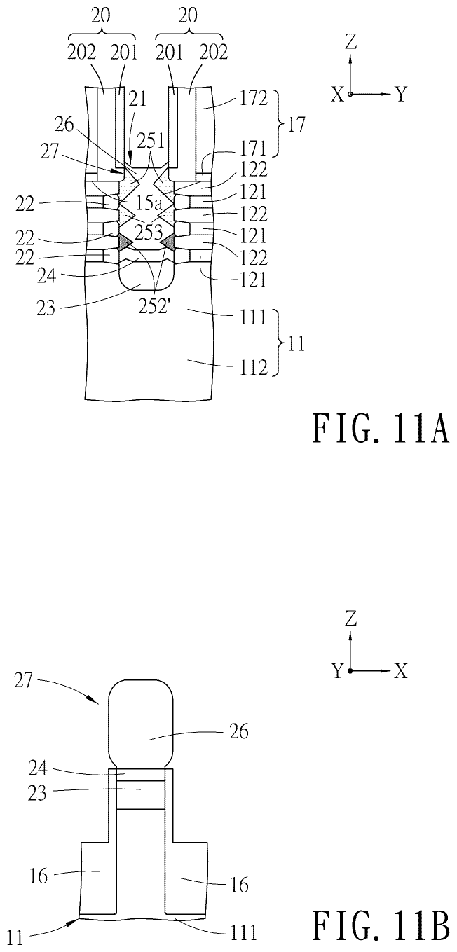

Referring to FIG. 1A and the example illustrated in FIGS. 10A and 10B, the method 100A then proceeds to step S09, where an ion implantation process is performed on the structure shown in FIGS. 9A and 9B. FIG. 10B illustrates a structure obtained after step S09, and the structure shown in FIG. 10B is the same as that shown in FIG. 9B. After this step, the upper epitaxial portions 251′ and the intermediate epitaxial portions 253′ are amorphized. In some embodiments, the ion implantation process may be a germanium ion implantation process or a silicon ion implantation process. Other suitable ion implantation processes are within the contemplated scope of the present disclosure. In other words, a dopant introduced into the upper epitaxial portions 251′ and the intermediate epitaxial portions 253′ by the ion implantation process includes, for example, but not limited to, silicon or germanium. Other suitable dopants are within the contemplated scope of the present disclosure. In some embodiments, the ion implantation process may be a directional ion implantation process (shown as solid arrows in FIG. 10A). In some embodiments, the ion implantation process is performed at an energy ranging from about 5 keV to about 24 keV. If the energy of the ion implantation process is lower than 5 keV, the upper epitaxial portions 251′ and the intermediate epitaxial portions 253′ may not be effectively amorphized. If the energy of the ion implantation process is greater than 24 keV, the lower epitaxial portions 252′ may be also amorphized, which is not advantageous for bottom-up growth of a plurality of second epitaxial layers 26 (see FIG. 11A), and which may result in formation of defects (e.g., voids) in the second epitaxial layers 26. In some embodiments, the ion implantation process is performed at a dose ranging from about 1×10¹⁴/cm⁻² to about 1×10¹⁵/cm⁻². If the dose of the ion implantation process is lower than 1×10¹⁴/cm⁻², the upper epitaxial portions 251′ and the intermediate epitaxial portions 253′ may not be effectively amorphized, which is not advantageous for the bottom-up growth of the second epitaxial layers 26, and which may result in the formation of defects in the second epitaxial layers 26. If the dose of the ion implantation process is greater than 1×10¹⁵/cm⁻², the channel features 122 (e.g., uppermost ones and intermediate ones of the channel features 122) may be damaged. The uppermost ones of the channel features 122 are distal from the semiconductor substrate 11, the lowermost ones of the channel features 122 are proximate to the semiconductor substrate 11, and each of the intermediate ones of the channel features 122 is located between a corresponding one of the uppermost ones of the channel features 122 and a corresponding one of the lowermost ones of the channel features 122.

In some embodiments, the upper epitaxial portions 251′ that are amorphized may be referred to as upper epitaxial features 251, and the intermediate epitaxial portions 253′ that are amorphized may be referred to as intermediate epitaxial features 253. In some embodiments, a size of the upper epitaxial feature 251 may be larger than that of the upper epitaxial portion 251′, and a size of the intermediate epitaxial feature 253 may be larger than that of the intermediate epitaxial portions 253′.

Referring to FIG. 1A and the example illustrated in FIGS. 11A and 11B, the method 100A then proceeds to step S10, where the second epitaxial layers 26 are formed to fill the source/drain trenches 21, respectively. FIG. 11B illustrates a structure obtained after step S10, and the structure shown in FIG. 11B is similar to that shown in FIG. 10B, except for inclusion of the second epitaxial layer 26. In some embodiments, each of the second epitaxial layers 26 may include, for example, but not limited to, silicon, silicon germanium, silicon boron, silicon phosphide, silicon arsenic, or combinations thereof. In some embodiments in which the PMOSFETs are to be formed, each of the second epitaxial layers 26 includes or is made of, for example, but not limited to, silicon, silicon germanium, silicon boron, or combinations thereof. In some embodiments in which the NMOSFETs are to be formed, each of the second epitaxial layers 26 includes or is made of, for example, but not limited to, silicon, silicon germanium, silicon phosphide, silicon arsenic, or combinations thereof. Other suitable materials for forming the second epitaxial layers 26 are within the contemplated scope of the present disclosure. In some embodiments, the second epitaxial layers 26 may be formed by a suitable epitaxial growth process, for example, but not limited to, the SEG process. Other suitable processes for forming the second epitaxial layers 26 are within the contemplated scope of the present disclosure. In some embodiments, each of the second epitaxial layers 26, corresponding ones of the upper epitaxial features 251, corresponding ones of the intermediate epitaxial features 253, and corresponding ones of the lower epitaxial portions 252′ may be collectively referred to as a source/drain portion 27 (i.e., a plurality of the source/drain portions 27 are formed after this step).

By performing the ion implantation process to amorphize the upper epitaxial portions 251′ and the intermediate epitaxial portions 253′, lateral merge of the material of the second epitaxial layer 26 in the upper trench portion 212 of the source/drain trench 21 can be reduced or eliminated during an early stage of forming the second epitaxial layer 26, which is advantageous for formation of the second epitaxial layer 26 without formation of defects (e.g., voids).

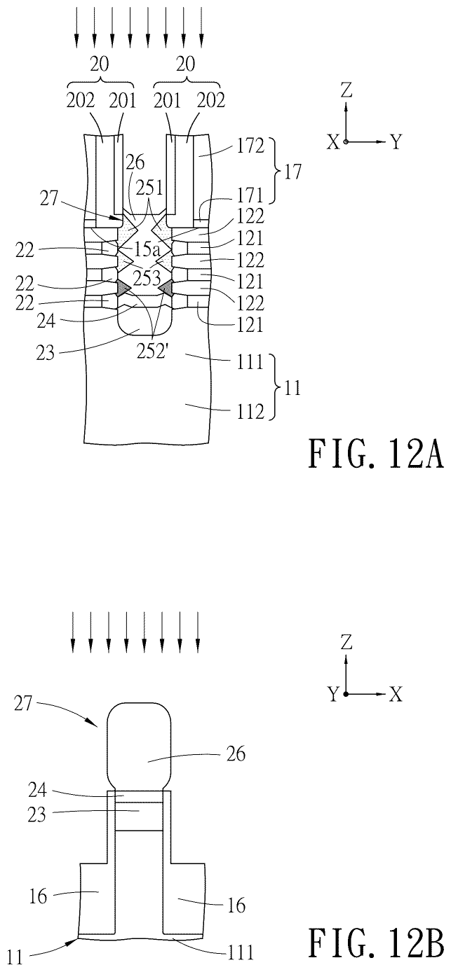

Referring to FIG. 1B and the example illustrated in FIGS. 12A and 12B, the method 100A then proceeds to step S11, where an implantation process is performed on the structure shown in FIGS. 11A and 11B. FIG. 12B illustrates a structure obtained after step S11, and the structure shown in FIG. 12B is the same as that shown in FIG. 11B. In some embodiments, the implantation process may be performed to introduce a p-type dopant into corresponding ones of the source/drain portions 27, so that the corresponding ones of the source/drain portions 27 have a p-type conductivity and may function as a source or a drain for PMOSFETs. In some embodiments, the p-type dopant may be, for example, but not limited to, boron, aluminum, or gallium. Other suitable p-type dopants are within the contemplated scope of the present disclosure. In some alternative embodiments, the implantation process may be performed to introduce an n-type dopant into corresponding ones of the source/drain portions 27, so that the corresponding ones of the source/drain portions 27 have an n-type conductivity and may function as a source or a drain for NMOSFETs. In some embodiments, the n-type dopant may be, for example, but not limited to, nitrogen, phosphorous, or arsenic. Other suitable n-type dopants are within the contemplated scope of the present disclosure.

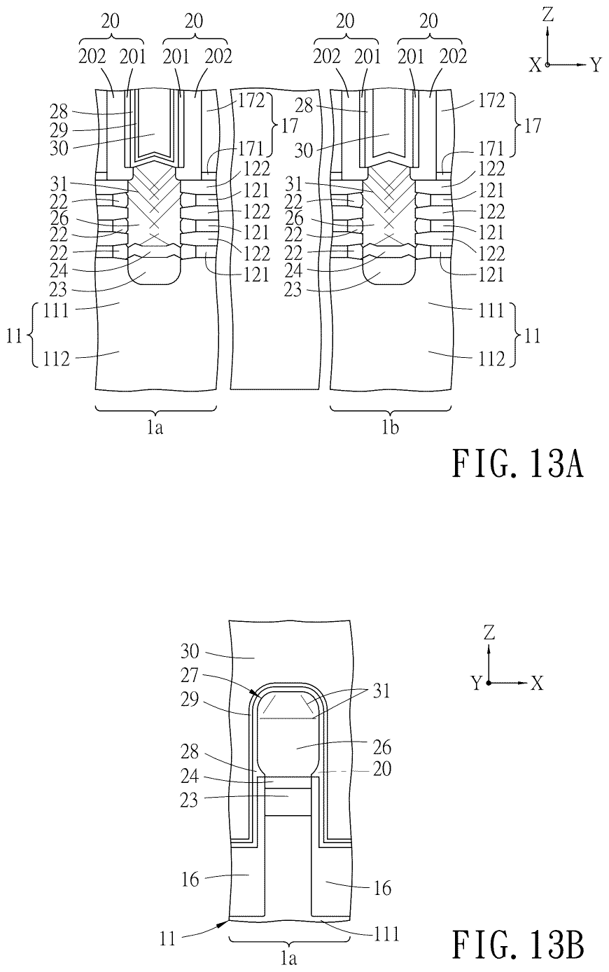

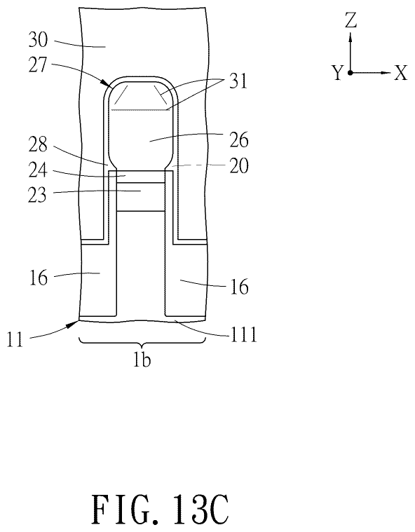

Referring to the example illustrated in FIGS. 13A to 13C, in some embodiments, the semiconductor substrate 11 may include a first region 1a for the first semiconductor device 200A to be subsequently formed thereon, and a second region 1b for the second semiconductor device 200B to be subsequently formed thereon. After performing the implantation process (i.e., step S11), the structure shown in FIG. 12A is formed on each of the first region 1a and the second region 1b.

Referring to FIG. 1B and the example illustrated in FIGS. 13A to 13C, the method 100A then proceeds to step S12, where a plurality of contact etch stop portions 28, a liner 29, and a plurality of inter-layer dielectric (ILD) portions 30 are formed. FIG. 13A illustrates a first structure and a second structure which are formed on the first region 1a and the second region 1b, respectively, after step S12. FIG. 13B illustrates the first structure obtained after step S12, and the structure shown in FIG. 13B is similar to that shown in FIG. 12B except that the contact etch stop portions 28, the liner 29, and the ILD portions 30 are formed. FIG. 13C illustrates the second structure obtained after step S12, and the structure shown in FIG. 13C is similar to that shown in FIG. 12B except that the contact etch stop portions 28, and the ILD portions 30 are formed. As shown in FIGS. 13A and 13B, the liner 29 is only formed in the first structure located on the first region 1a.

In this step, a contact etch stop layer (not shown) for forming the contact etch stop portions 28 is conformally formed on the structure shown in FIG. 12A, which is located on each of the first region 1a and the second region 1b. In some embodiments, the contact etch stop layer may include, for example, but not limited to, silicon nitride, carbon-doped silicon nitride, or a combination thereof. Other suitable materials for forming the contact etch stop layer are within the contemplated scope of the present disclosure. In some embodiments, the contact etch stop layer may be formed by a suitable deposition process, for example, but not limited to, CVD. Other suitable deposition processes for forming the contact etch stop layer are within the contemplated scope of the present disclosure.

Next, a liner layer (not shown) for forming the liner 29 is formed on the first structure obtained after formation of the contact etch stop layer. In some embodiments, the liner layer may include, for example, but not limited to, silicon, germanium, or a combination thereof. Other suitable materials for forming the liner layer are within the contemplated scope of the present disclosure. In some embodiments, the liner layer may be formed by a suitable deposition process, for example, but not limited to, CVD or ALD. Other suitable deposition processes for forming the liner layer are within the contemplated scope of the present disclosure. In some embodiments, the liner layer may have a thickness ranging from about 1 nm to about 3 nm. The second structure (to be subsequently formed into the second semiconductor device 200B) on the second region 1b is covered by a mask layer (for example, but not limited to, a photoresist layer) prior to formation of the liner layer on the first structure, and the mask layer is removed by a suitable removal process (for example, but not limited to, an etching process or an ashing process) after the liner layer is formed on the first structure.

Thereafter, a dielectric material layer (not shown) for forming the ILD portions 30 is formed on the first and second structures obtained after formation of the liner layer. In some embodiments, the dielectric material layer may include, for example, but not limited to, silicon oxide, silicon nitride, silicon oxynitride, other low-k dielectric materials, or combinations thereof. Other suitable materials for forming the dielectric material layer are within the contemplated scope of the present disclosure. In some embodiments, the dielectric material layer may be formed by a suitable deposition process, for example, but not limited to, CVD. Other suitable deposition processes for forming the dielectric material layer are within the contemplated scope of the present disclosure.

Then, a thermal treatment is performed on the first and second structures obtained after formation of the dielectric material layer. The thermal treatment is utilized to recrystallize the source/drain portions 27 so as to increase crystallinity thereof. In some embodiments, the thermal treatment is an annealing treatment, which is performed at a temperature ranging from about 900° C. to about 1200° C. Other suitable thermal treatments are within the contemplated scope of the present disclosure. If the temperature of the thermal treatment is lower than 900° C., extension of a time period of the thermal treatment is required so that the source/drain portions 27 have better crystallinity. If the temperature of the thermal treatment is greater than 1200° C., function of other components may be adversely affected. In some embodiments, crystallinity of the source/drain portions 27 may reach a saturated level during the thermal treatment. In some embodiments, the thermal treatment may induce a compressive stress in the source/drain portions 27, and the compressive stress may transmit from the source/drain portions 27 to the channel features 122.

After that, an excess portion of the dielectric material layer, an excess portion of the liner layer, an excess portion of the contact etch stop layer, the mask portions 19, the mask portions 18, and portions of the fin spacers 20 are removed by a suitable planarization process, thereby obtaining the contact etch stop portions 28 (i.e., remaining portions of the contact etch stop layer), the liner 29 (i.e., a remaining portion of the liner layer), and the ILD portions 30 (i.e., remaining portions of the dielectric material layer). In some embodiments, the planarization process may be, for example, but not limited to, CMP or other suitable planarization processes. In some embodiments, a portion of the each of the dummy gate electrodes 172 may be removed after the planarization process.

As the thickness of each of the epitaxial portions decreases (e.g., ranging from about 2 nm to about 4 nm or from about 1 nm to about 3 nm), the crystallinity of the source/drain portions 27 may increase after the thermal treatment. In some embodiments, as the thickness of each of the epitaxial portions decreases by a value ranging from about 1 nm to about 2 nm, the crystallinity of the source/drain portions 27 may increase by a value ranging from about 0.90% to 2.60% after the thermal treatment.

In some embodiments, the liner layer may be oxidized during formation of the dielectric material layer, and a compressive stress may be induced in the dielectric material layer, the liner layer, and the contact etch stop layer. In some embodiments, the induced compressive stress may range from about 1 GPa to about 1.5 GPa. The liner 29 (formed from the liner layer) may act as a stressor to maintain the stress of the source/drain portions 27 during the thermal treatment (the stress of the source/drain portions 27 may be released due to stacking faults 31 being formed in the source/drain portions 27 during the thermal treatment). Each of the stacking faults 31 is a lattice dislocation (an irregularity of atomic arrangement) occurred in the source/drain portions 27 when at least one atom layer interrupts a normal periodic stacking of atom layers. If the thickness of the liner layer is less than 1 nm, oxidation of the liner layer may be reduced during the formation of the dielectric material layer (for forming the ILD portions 30). In this case, the liner 29 may not be able to maintain the stress of the source/drain portions 27 during the thermal treatment. If the thickness of the liner layer is greater than 3 nm, the formation of the dielectric material layer may be adversely affected, and the oxidation of the liner layer may be further affected, and thus the liner 29 may not be able to maintain the stress of the source/drain portions 27 during the thermal treatment.

In some embodiments, a density of the stacking faults 31 distributed in upper and intermediate parts of the source/drain portion 27 is greater than that of the stacking faults 31 distributed in a lower part of the source/drain portion 27. The upper part of the source/drain portion 27 is proximate to the uppermost ones of the channel features 122, the intermediate part of the source/drain portion 27 is proximate to the intermediate ones of the channel features 122, and the lower part of the source/drain portion 27 is proximate to the lowermost ones of the channel features 122.

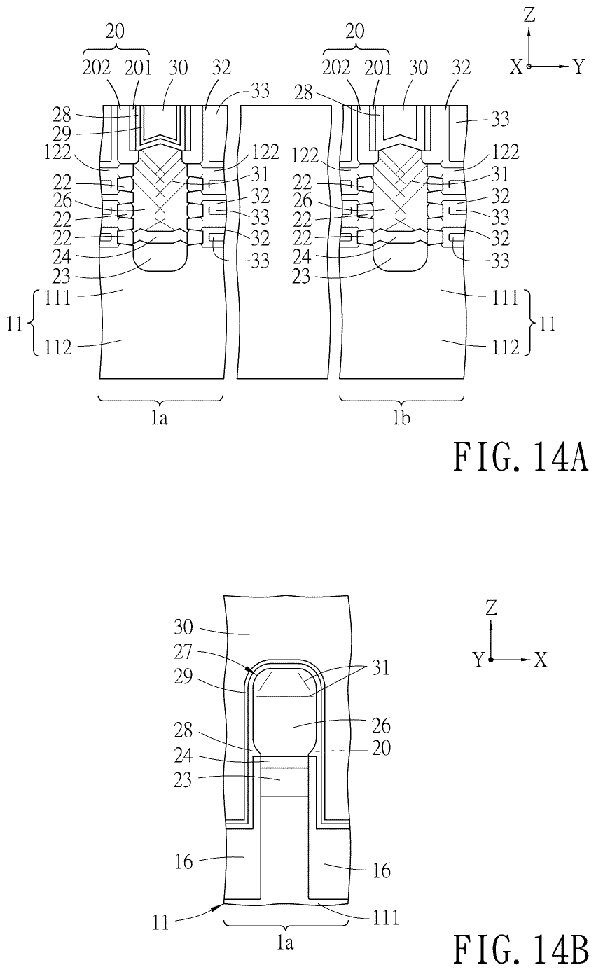

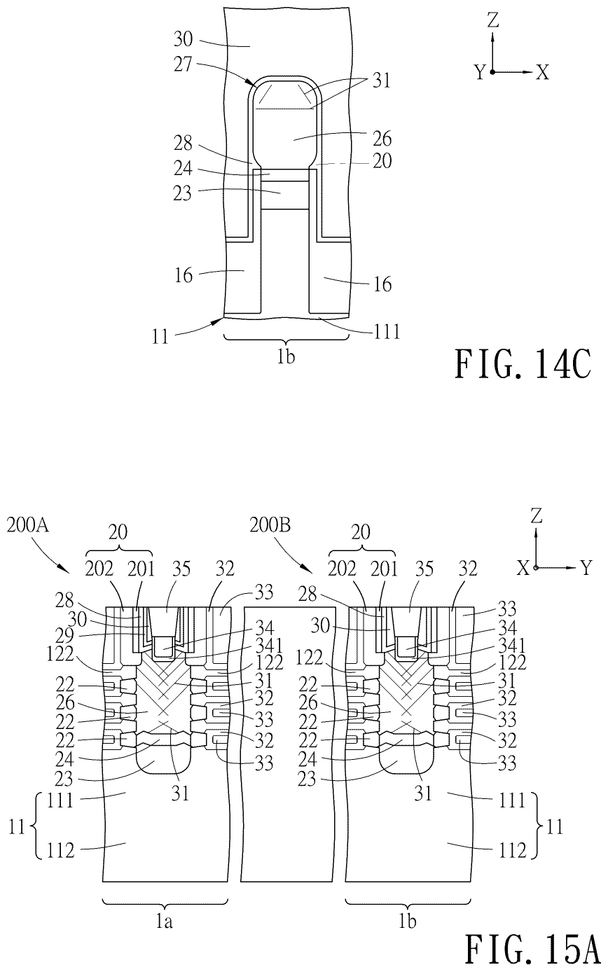

Referring to FIG. 1B and the example illustrated in FIGS. 14A to 14C, the method 100A then proceeds to step S13, where the sacrificial features 121 and the dummy poly gates 17 shown in FIG. 13A are removed, followed by sequentially forming a plurality of gate dielectrics 32 and a plurality of gate electrodes 33. FIG. 14B illustrates a structure obtained after step S13, and the structure shown in FIG. 14B is the same as that shown in FIG. 13B. FIG. 14C illustrates a structure obtained after step S13, and the structure shown in FIG. 14C is the same as that shown in FIG. 13C.

In this step, the sacrificial features 121 and the dummy poly gates 17 are removed by two or more etching processes, so as to form a plurality of lower cavities and a plurality of upper cavities (not shown). In some embodiments, the etching process for removing the dummy poly gates 17 may be a wet etching process, a dry etching process, or a combination thereof. In some embodiments, the etching process for removing the sacrificial features 121 may be an isotropic dry etching process, an isotropic wet etching process, or a combination thereof. Other suitable etching processes for removing the sacrificial features 121 and the dummy poly gates 17 are within the contemplated scope of the present disclosure. The lower cavities are defined by the inner spacers 22 and the channel features 122, and the upper cavities are defined by the fin spacers 20 and the uppermost ones of the channel features 122. In some embodiments, each of the channel features 122 may be slightly etched after the etching processes.

Next, a gate dielectric layer (not shown) for forming the gate dielectrics 32 is formed in the lower and upper cavities. In some embodiments, the gate dielectric layer may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. Other suitable materials for forming the gate dielectric layer are within the contemplated scope of the present disclosure. In some embodiments, the gate dielectric layer may be formed by a suitable deposition process, for example, but not limited to, CVD or ALD. Other suitable processes for forming the gate dielectric layer are within the contemplated scope of the present disclosure.

Thereafter, a gate electrode layer (not shown) for forming the gate electrodes 33 is formed such that the gate electrode layer fills the lower and upper cavities. In some embodiments, the gate electrode layer may include, for example, but not limited to, aluminum, copper, tungsten, cobalt, ruthenium, titanium, tantalum, molybdenum, nickel, platinum, titanium nitride, tantalum nitride, or combinations thereof. Other suitable materials for forming the gate electrode layer are within the contemplated scope of the present disclosure. In some embodiments, the gate electrode layer may be formed by a suitable deposition process, for example, but not limited to, CVD. Other suitable deposition processes for forming the gate electrode layer are within the contemplated scope of the present disclosure.

Then, a planarization process (e.g., CMP or other suitable planarization processes) is performed to remove an excess portion of the gate dielectric layer, an excess portion of the gate electrode layer, upper parts of the fin spacers 20, upper parts of the contact etch stop portions 28, an upper part of the liner 29, and upper parts of the ILD portions 30, thereby obtaining the gate dielectrics 32 and the gate electrodes 33. In some embodiments, each of the gate dielectrics 32 and a corresponding one of the gate electrodes 33 may be collectively referred to as a metal gate (i.e., the metal gates are formed), which is configured to surround corresponding ones of the channel features 122.

In some embodiments, after removal of the sacrificial features 121 and the dummy poly gates 17 and before formation of the gate dielectric layer, a plurality of interfacial features (not shown) are formed. In some embodiments, the interfacial features may include, for example, but not limited to, silicon oxide. Other suitable materials for forming the interfacial features are within the contemplated scope of the present disclosure. In some embodiments, the interfacial features may be formed by a suitable process, for example, but not limited to, a wet chemical process, ALD, or thermal oxidation. Other suitable processes for forming the interfacial features are within the contemplated scope of the present disclosure. Each of the interfacial features surrounds a corresponding one of the channel features 122 and is covered by a corresponding one of the gate dielectrics 32.

Referring to FIG. 1B and the example illustrated in FIGS. 15A to 15C, the method 100A then proceeds to step S14, where a plurality of silicide features 34 and a plurality of conductive features 35 are formed. FIG. 15B illustrates a structure obtained after step S14, and the structure shown in FIG. 15B is similar to that shown in FIG. 14B, except for inclusion of the silicide feature 34 and the conductive feature 35. FIG. 15C illustrates a structure obtained after step S14, and the structure shown in FIG. 15C is similar to that shown in FIG. 14C, except for inclusion of the silicide feature 34 and the conductive feature 35.

In this step, a photolithography process is conducted to form a plurality of through holes (not shown) which respectively penetrate corresponding ones of the ILD portions 30, the liner 29, and corresponding ones of the contact etch stop portions 28, followed forming the silicide features 34 in the through holes. Each of the silicide features 34 is formed between a corresponding one of the source/drain portions 27 and a corresponding one of the conductive features 35. In some embodiments, each of the silicide features 34 may include, for example, but not limited to, titanium silicide. Other suitable materials for forming the silicide features 34 are within the contemplated scope of the present disclosure.

In some embodiments, a silicide interfacial layer 341 may be formed between each of the silicide features 34 and a corresponding one of the source/drain portions 27. In some embodiments, the silicide interfacial layer 341 may include a combination of titanium silicide and silicon, a combination of titanium silicide and germanium, or a combination of titanium silicide, silicon, and germanium. Silicon, germanium, or a combination of silicon and germanium comes from residue of the liner 29 which is penetrated by the through hole).

Next, the conductive features 35 are formed on corresponding ones of the silicide features 34. In some embodiments, each of the conductive features 35 may include, for example, but not limited to, aluminum, copper, tungsten, cobalt, ruthenium, titanium, tantalum, molybdenum, nickel, platinum, or combinations thereof. Other suitable materials for forming the conductive features 35 are within the contemplated scope of the present disclosure. In some embodiments, the conductive features 35 may be formed by sequentially depositing a conductive material layer for forming the conductive features 35 such that the conductive material layer fills the through holes, and then conducting a planarization process (for example, but not limited to, CMP or other suitable planarization processes) to remove an excess portion of the conductive material layer, so as to obtain the conductive features 35.

After step S14, the first semiconductor device 200A and the second semiconductor device 200B are obtained. In some embodiments, the first semiconductor device 200A is a PMOSFET and the second semiconductor device 200B is a NMOSFET.

In a semiconductor device of this disclosure, formation of a plurality of source/drain portions on a semiconductor substrate includes: (i) forming a first epitaxial layer (including upper epitaxial portions, intermediate epitaxial portions, and lower epitaxial portions), (ii) amorphizing the upper and intermediate epitaxial portions (distal from the semiconductor substrate), (iii) forming a second epitaxial layer on the semiconductor substrate, and over the upper and intermediate epitaxial portions that are amorphized and the lower epitaxial portions, and (iv) subjecting the upper and intermediate epitaxial portions to recrystallization after formation of the second epitaxial layer. By performing the aforesaid steps, formation of defects (e.g., voids) in the source/drain portions thus formed may be reduced.

In accordance with some embodiments of the present disclosure, a method for manufacturing a semiconductor device includes: forming a fin structure on a substrate, the fin structure including a plurality of sacrificial layer portions and a plurality of channel layer portions which are alternately stacked in a normal direction relative to the substrate; forming a trench that penetrates the fin structure, so that the plurality of sacrificial layer portions are formed into a plurality of sacrificial features, and the plurality of channel layer portions are formed into a plurality of channel features; forming a plurality of upper epitaxial portions, a plurality of lower epitaxial portions and a plurality of intermediate epitaxial portions in the trench, each of the plurality of upper epitaxial portions being distal from the substrate in the normal direction and disposed at a side of a corresponding one of upper ones of the plurality of channel features, each of the plurality of lower epitaxial portions being proximate to the substrate in the normal direction and disposed at a side of a corresponding one of lower ones of the plurality of channel features, each of the plurality of intermediate epitaxial portions being located between a corresponding one of the upper ones of the plurality of upper epitaxial portions and a corresponding one of the lower ones of the plurality of lower epitaxial portions in the normal direction, and disposed at a side of a corresponding one of intermediate ones of the plurality of channel features; the upper ones of the plurality of channel features being distal from the substrate, the lower ones of the plurality of channel features being proximate to the substrate, the intermediate ones of the plurality of channel features being located between the upper ones of the plurality of channel features and the lower ones of the plurality of channel features; amorphizing the plurality of upper epitaxial portions and the plurality of intermediate epitaxial portions; forming an epitaxial layer to fill the trench; and subjecting the plurality of upper epitaxial portions and the plurality of intermediate epitaxial portions to recrystallization.

In accordance with some embodiments of the present disclosure, each of the plurality of upper epitaxial portions, the plurality of lower epitaxial portions, and the plurality of intermediate epitaxial portions has a thickness ranging from about 3 nm to about 5 nm.

In accordance with some embodiments of the present disclosure, each of the plurality of upper epitaxial portions, the plurality of lower epitaxial portions, and the plurality of intermediate epitaxial portions includes silicon, silicon germanium, silicon boron, silicon phosphide, silicon arsenic, or combinations thereof.

In accordance with some embodiments of the present disclosure, the plurality of upper epitaxial portions and the plurality of intermediate epitaxial portions are amorphized by an ion implantation process.

In accordance with some embodiments of the present disclosure, the ion implantation process is a germanium ion implantation process or a silicon ion implantation process.

In accordance with some embodiments of the present disclosure, the ion implantation process is performed at an energy ranging from about 5 keV to about 24 keV.

In accordance with some embodiments of the present disclosure, the ion implantation process is performed at a dose ranging from about 1×10¹⁴/cm⁻² to about 1×10¹⁵/cm⁻².

In accordance with some embodiments of the present disclosure, the recrystallization is performed by an annealing treatment at a temperature ranging from about 900° C. to about 1200° C.

In accordance with some embodiments of the present disclosure, a method for manufacturing a semiconductor device includes: forming two stack sections on a substrate in a first direction normal to the substrate, the two stack sections being spaced apart from each other in a second direction transverse to the first direction and parallel to the substrate, each of the two stack sections including a plurality of sacrificial features and a plurality of channel features which are alternately stacked in the first direction; forming a plurality of upper epitaxial portions, a plurality of lower epitaxial portions and a plurality of intermediate epitaxial portions between the two stack sections, each of the plurality of upper epitaxial portions being distal from the substrate in the first direction and disposed at a side of a corresponding one of upper ones of the plurality of channel features, each of the plurality of lower epitaxial portions being proximate to the substrate in the first direction and disposed at a side of a corresponding one of lower ones of the plurality of the channel features, each of the plurality of intermediate epitaxial portions being located between a corresponding one of the upper ones of the plurality of upper epitaxial portions and a corresponding one of the lower ones of the plurality of lower epitaxial portions in the first direction, and disposed at a side of a corresponding one of intermediate ones of the plurality of channel features, the upper ones of the plurality of channel features being distal from the substrate, the lower ones of the plurality of channel features being proximate to the substrate, the intermediate ones of the plurality of channel features being located between the upper ones of the plurality of channel features and the lower ones of the plurality of channel features; amorphizing the plurality of upper epitaxial portions and the plurality of intermediate epitaxial portions; forming an epitaxial layer on the substrate and between the two stack sections so as to cover the plurality of upper epitaxial portions, the plurality of lower epitaxial portions and the plurality of intermediate epitaxial portions; and subjecting the plurality of upper epitaxial portions, the plurality of lower epitaxial portions, the plurality of intermediate epitaxial portions, and the epitaxial layer to a thermal treatment.

In accordance with some embodiments of the present disclosure, the method for manufacturing the semiconductor device further includes forming a contact etch stop portion on the epitaxial layer opposite to the substrate; forming a liner on the contact etch stop portion opposite to the epitaxial layer; and forming an inter-layer dielectric portion on the liner opposite to the contact etch stop portion.

In accordance with some embodiments of the present disclosure, the liner is formed by a chemical vapor deposition process or an atomic layer deposition process.

In accordance with some embodiments of the present disclosure, the liner is oxidized during formation of the inter-layer dielectric portion.

In accordance with some embodiments of the present disclosure, the method for manufacturing a semiconductor device further includes, after the thermal treatment, forming a conductive feature that extends through the inter-layer dielectric portion, the liner and the contact etch stop portion, so that the conductive feature is electrically connected to the epitaxial layer.

In accordance with some embodiments of the present disclosure, after amorphizing the plurality of upper epitaxial portions and the plurality of intermediate epitaxial portions, a size of each of the plurality of upper epitaxial portions and the plurality of intermediate epitaxial portions increases.

In accordance with some embodiments of the present disclosure, a semiconductor device includes a substrate, a plurality of first channel features, a plurality of second channel features, a first metal gate, a second metal gate, and a source/drain portion. The plurality of first channel features and the plurality of second channel features are disposed on the substrate. The first metal gate is disposed to surround the plurality of first channel features. The second metal gate is disposed to surround the plurality of second channel features. The source/drain portion is disposed on the substrate and between the plurality of first channel features and the plurality of second channel features, and includes a plurality of stacking faults.

In accordance with some embodiments of the present disclosure, the semiconductor device further includes a contact etch stop portion disposed on the source/drain portion opposite to the substrate; a liner disposed on the contact etch stop portion opposite to the source/drain portion; an inter-layer dielectric portion disposed on the liner opposite to the contact etch stop portion; and a conductive feature extending through the inter-layer dielectric portion, the liner, and the contact etch stop portion and being electrically connected to the source/drain portion.

In accordance with some embodiments of the present disclosure, the liner has a thickness ranging from about 1 nm to about 2 nm.

In accordance with some embodiments of the present disclosure, the liner includes silicon, germanium, or a combination thereof.

In accordance with some embodiments of the present disclosure, the semiconductor device further includes a silicide feature disposed between the source/drain portion and the conductive feature, and a silicide interfacial layer disposed among the source/drain portion, the liner and the silicide feature.

In accordance with some embodiments of the present disclosure, a density of the plurality of stacking faults exhibits a decreasing trend in a direction from an upper part of the source/drain portion to a lower part of the source/drain portion. The upper part and the lower part of the source/drain portion are distal from and proximate to the substrate, respectively.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a fin structure on a substrate, the fin structure including a plurality of sacrificial layer portions and a plurality of channel layer portions which are alternately stacked in a normal direction relative to the substrate;
forming a trench that penetrates the fin structure, so that the plurality of sacrificial layer portions are formed into a plurality of sacrificial features, and the plurality of channel layer portions are formed into a plurality of channel features;
forming a plurality of upper epitaxial portions, a plurality of lower epitaxial portions and a plurality of intermediate epitaxial portions in the trench, each of the plurality of upper epitaxial portions being distal from the substrate in the normal direction and disposed at a side of a corresponding one of upper ones of the plurality of channel features, each of the plurality of lower epitaxial portions being proximate to the substrate in the normal direction and disposed at a side of a corresponding one of lower ones of the plurality of channel features, each of the plurality of intermediate epitaxial portions being located between a corresponding one of the upper ones of the plurality of upper epitaxial portions and a corresponding one of the lower ones of the plurality of lower epitaxial portions in the normal direction, and disposed at a side of a corresponding one of intermediate ones of the plurality of channel features, the upper ones of the plurality of channel features being distal from the substrate, the lower ones of the plurality of channel features being proximate to the substrate, the intermediate ones of the plurality of channel features being located between the upper ones of the plurality of channel features and the lower ones of the plurality of channel features;
amorphizing the plurality of upper epitaxial portions and the plurality of intermediate epitaxial portions;
forming an epitaxial layer to fill the trench; and
subjecting the plurality of upper epitaxial portions and the plurality of intermediate epitaxial portions to recrystallization.

2. The method as claimed in claim 1, wherein each of the plurality of upper epitaxial portions, the plurality of lower epitaxial portions, and the plurality of intermediate epitaxial portions has a thickness ranging from 3 nm to 5 nm.

3. The method as claimed in claim 1, wherein each of the plurality of upper epitaxial portions, the plurality of lower epitaxial portions, and the plurality of intermediate epitaxial portions includes silicon, silicon germanium, silicon boron, silicon phosphide, silicon arsenic, or combinations thereof.

4. The method as claimed in claim 1, wherein the plurality of upper epitaxial portions and the plurality of intermediate epitaxial portions are amorphized by an ion implantation process.

5. The method as claimed in claim 4, wherein the ion implantation process is a germanium ion implantation process or a silicon ion implantation process.

6. The method as claimed in claim 4, wherein the ion implantation process is performed at an energy ranging from 5 keV to 24 keV.

7. The method as claimed in claim 4, wherein the ion implantation process is performed at a dose ranging from 1×10¹⁴/cm⁻² to 1×10¹⁵/cm⁻².

8. The method as claimed in claim 1, wherein the recrystallization is performed by an annealing treatment at a temperature ranging from 900° C. to 1200° C.

9. A method for manufacturing a semiconductor device, comprising:
forming two stack sections on a substrate in a first direction normal to the substrate, the two stack sections being spaced apart from each other in a second direction transverse to the first direction and parallel to the substrate, each of the two stack sections including a plurality of sacrificial features and a plurality of channel features which are alternately stacked in the first direction;
forming a plurality of upper epitaxial portions, a plurality of lower epitaxial portions and a plurality of intermediate epitaxial portions between the two stack sections, each of the plurality of upper epitaxial portions being distal from the substrate in the first direction and disposed at a side of a corresponding one of upper ones of the plurality of channel features, each of the plurality of lower epitaxial portions being proximate to the substrate in the first direction and disposed at a side of a corresponding one of lower ones of the plurality of the channel features, each of the plurality of intermediate epitaxial portions being located between a corresponding one of the upper ones of the plurality of upper epitaxial portions and a corresponding one of the lower ones of the plurality of lower epitaxial portions in the first direction, and disposed at a side of a corresponding one of intermediate ones of the plurality of channel features, the upper ones of the plurality of channel features being distal from the substrate, the lower ones of the plurality of channel features being proximate to the substrate, the intermediate ones of the plurality of channel features being located between the upper ones of the plurality of channel features and the lower ones of the plurality of channel features;
amorphizing the plurality of upper epitaxial portions and the plurality of intermediate epitaxial portions;
forming an epitaxial layer on the substrate and between the two stack sections so as to cover the plurality of upper epitaxial portions, the plurality of lower epitaxial portions and the plurality of intermediate epitaxial portions; and
subjecting the plurality of upper epitaxial portions, the plurality of lower epitaxial portions, the plurality of intermediate epitaxial portions, and the epitaxial layer to a thermal treatment.

10. The method as claimed in claim 9, further comprising:
forming a contact etch stop portion on the epitaxial layer opposite to the substrate;
forming a liner on the contact etch stop portion opposite to the epitaxial layer; and
forming an inter-layer dielectric portion on the liner opposite to the contact etch stop portion.

11. The method as claimed in claim 10, wherein the liner is formed by a chemical vapor deposition process or an atomic layer deposition process.

12. The method as claimed in claim 10, wherein the liner is oxidized during formation of the inter-layer dielectric portion.

13. The method as claimed in claim 10, further comprising, after the thermal treatment, forming a conductive feature that extends through the inter-layer dielectric portion, the liner and the contact etch stop portion, so that the conductive feature is electrically connected to the epitaxial layer.

14. The method as claimed in claim 10, wherein after amorphizing the plurality of upper epitaxial portions and the plurality of intermediate epitaxial portions, a size of each of the plurality of upper epitaxial portions and the plurality of intermediate epitaxial portions increases.

15. A semiconductor device, comprising:
a substrate;
a plurality of first channel features and a plurality of second channel features which are disposed on the substrate;
a first metal gate disposed to surround the plurality of first channel features;
a second metal gate disposed to surround the plurality of second channel features; and
a source/drain portion disposed on the substrate and between the plurality of first channel features and the plurality of second channel features, and including a plurality of stacking faults.

16. The semiconductor device as claimed in claim 15, further comprising:
a contact etch stop portion disposed on the source/drain portion opposite to the substrate;
a liner disposed on the contact etch stop portion opposite to the source/drain portion;
an inter-layer dielectric portion disposed on the liner opposite to the contact etch stop portion; and
a conductive feature extending through the inter-layer dielectric portion, the liner, and the contact etch stop portion and being electrically connected to the source/drain portion.

17. The semiconductor device as claimed in claim 16, wherein the liner has a thickness ranging from 1 nm to 2 nm.

18. The semiconductor device as claimed in claim 16, wherein the liner includes silicon, germanium, or a combination thereof.

19. The semiconductor device as claimed in claim 18, further comprising a silicide feature disposed between the source/drain portion and the conductive feature, and a silicide interfacial layer disposed among the source/drain portion, the liner and the silicide feature.

20. The semiconductor device as claimed in claim 15, wherein a density of the plurality of stacking faults exhibits a decreasing trend in a direction from an upper part of the source/drain portion to a lower part of the source/drain portion, the upper part and the lower part of the source/drain portion being distal from and proximate to the substrate, respectively.
